(19) United States
(12) Patent Application Publication
(10) Pub. No.: US 2008/0079455 A1
(43) Pub. Date: Apr. 3, 2008

(54) IC Chip Package, Test Equipment and Interface for Performing a Functional Test of a Chip Contained Within Said Chip Package

(76) Inventors: Joerg Vollrath, Olching (DE); Marcin Gnat, Mering (DE); Ralf Schneider, Muenchen (DE)

Correspondence Address: SLATER & MATSIL, L.L.P., 17950 PRESTON ROAD, SUITE 1000, DALLAS, TX, 75252, US

(21) Appl. No.: 11/866,677

(22) Filed: Oct. 3, 2007

Related U.S. Application Data
(63) Continuation of application No. PCT/EP2005/004039, filed on Apr. 15, 2005.

(51) Int. Cl. G01R 31/26

(52) U.S. Cl. 324/763

(57) ABSTRACT

An interface between a test access port of an integrated circuit chip and a test equipment, which is designed to perform a functional test of the chip, is provided. The interface includes electric pads on either sides of the chip and the test equipment. The pads are arranged to interact by means of capacitive coupling, when a test data signal is input to one of the pads. Preferably, both pads are connected with either a receiver or a driver depending on the direction of the data flow. The electric pads relating to the chip's side may be arranged within the wiring substrate of a chip package, particularly along edge portion of the substrate, which encompasses an inner portion of the substrate, in which a ball-grid-array can be formed.

This application is a continuation of co-pending International Application No. PCT/EP2005/004039, filed Apr. 15, 2005, which designated the United States and was published in English, and is incorporated herein by reference.

### TECHNICAL FIELD

The invention relates to an integrated circuit (IC) chip package, a test equipment for testing the IC chip packages and a specific interface for providing communication between the test equipment and the IC chip package. The invention particularly relates to a communication interface designed for functional tests of IC chips performed after their assembly into chip packages.

### BACKGROUND

Prior to the delivery to customers integrated circuit chips (IC chips) are typically formed into IC chip packages and arranged on printed circuit boards (PCB). Therein, electrical access to the chip functions is realized by arranging contact pads on the chip and bonding these pads to redistribution layers within a wiring substrate, that is, e.g., mounted to the chip by means of an adhesive layer. In order to protect the chip, it is also enclosed by a housing, which is, e.g., made of plastic. Redistribution layers serve to provide large-scale contacts from outside the package for electrical access to the chip inside the package.

The requirement of achieving higher densities of chips and chip packages on printed circuit boards recently led to the development of chip-scale packages. This means that the footprint of a chip package on a board roughly scales with the chip area. Consequently, a transition from the former TSOP technology towards ball-grid array arrangements of contacts had been initiated, wherein sets of contacts are arranged beneath the wiring substrate instead of a placement at its edges. The ball-like contacts each connect to a corresponding pad arranged on the printed circuit board. Each of the balls defines the distance between the chip package bottom side and the printed circuit board surface by means of its diameter. As there are no longer TSOP-wires at the edges of the chip packages, adjacent chip packages can be placed in close proximity to its neighbors.

One process performed during back-end technology is a functional test of the integrated circuit chips mounted to the boards. Such tests are applied using specific test equipment, in particular, automated test equipment (ATE). Generally, test data and instruction data are transferred to the chip within the chip package initiating desired test operations on these data and retrieving back the results of these operations from the chip.

The test data to be retrieved may comprise, e.g., results of a built-in self test, a vendor ID, etc. Test sequences may also involve varying internal chip voltages for test purposes for comparison with predetermined specifications. In order to transfer these data to the chip and to retrieve processed data from the chip, an electrical access has to be achieved with respect to the packaged chip.

This is usually accomplished by either contacting the former TSOP-wires on either sides of the chip package or by contacting specific pads arranged on the printed circuit board providing further access to the ball-like electrical contacts of the corresponding chip package. Such a contact of a test equipment is accomplished by means of electrodes, which are moveable by means of automated operation for the purpose of mass production.

As mentioned above, the increasing density of chip packages on a board and further, the development of stacking multiple chip packages, one above the other, has recently lead to the problem of how to get electrical access for the test equipment to a chip within a package. Extra pins, or balls, are costly with respect to the standardized ball-grid array layouts and the PCB boards are not prepared to wire those extra pins.

### SUMMARY OF THE INVENTION

In a first embodiment an integrated circuit chip package, includes an integrated circuit chip having a core logic and a test access port for performing a functional test of a chip circuitry and/or the core logic, a housing for protecting the chip, a wiring substrate for providing an electrical access to the core logic and the test access port, wherein at least one electric pad is provided as a capacitor electrode on a surface of the wiring substrate, which is electrically connected with the test access port and which is arranged to form a capacitor in combination with an external electric pad of an external test equipment, for transferring a signal between a test equipment and the test access port of the chip by means of capacitive coupling.

In another embodiment an interface performs a functional test of an integrated circuit chip, comprising at least a first electric pad and a driver circuit that is associated with the first electric pad, a second electric pad and a receiver circuit that is associated with the second electric pad, wherein both electric pads are arranged to form a capacitor when being brought into close proximity with respect to each other, one of both electric pads being arranged on a wiring substrate surface of an integrated circuit chip package, the other one of both pads being arranged on a test equipment, which is designed to perform the functional test of an integrated circuit chip.

According to embodiments of the invention, the communication between a test equipment and an IC-chip within a chip package is performed by means of capacitive coupling. The corresponding interface is established by means of forming pads, or more precisely electrical pads, as capacitor electrodes on both sides of the interface, i.e., within both communication partners.

On the side of the chip package, the electrical pad is preferably formed in the wiring substrate. It has been found that most BGA chip packages (BGA: ball-grid array) still have unused surface area near the edges beneath the chip package, i.e., on their bottom sides. This surface area is oriented towards the PCB when the chip package is mounted to that PCB. As a result, this space volume is quite inaccessible by electrodes trying to contact an additional pin, which is applied to the package according to common techniques.

However, an electric pad integrated in the wiring substrate does not consume this in any way small space volume and can be accessed by an electrode without strong mechanical pressure. An embodiment of the invention becomes particularly advantageous with respect to memory components, wherein memory modules are densely packed with memory chip packages. In this case, conventional access using electrodes to contact pins or wires is severely affected by that dense packing.

Embodiments of the invention also become particularly advantageous with respect to chip packages having ball-grid arrays for the same reasons as explained above, but the invention is not limited to this case. The difference between performing common chip functions and performing a functional test becomes most prominent with respect to the different modes of electrical access, e.g., direct electrical contact via ball-like pins versus via the electrical pads, which form capacitor electrodes, that provide the desired capacitive coupling.

The electrical pads formed within the wiring substrate or those formed by the electrodes of the test equipment or even both can be supplied with a layer of dielectric material to form a capacitor dielectric. Any suitable material is possible that achieves the desired capacitor characteristics, i.e., dielectric constant and/or thickness.

A further feature, that makes an electric pad forming a capacitor electrode of the capacitive interface differ from those ball-like pins or similar contacts providing direct access to the core logic of the chip (i.e., without capacitive coupling), is a driver or receiver circuit, respectively. A signal transferred over the capacitive interface will suffer from several effects such as parasitic capacitance, for which purpose the driver or receiver circuits are embodied in order to accurately recover the signal after being transferred.

According to one embodiment of the invention, a driver circuit comprises one inverter, and the receiver circuit comprises a first inverter and a second inverter which feeds back a signal output from the first inverter towards its corresponding signal input. Implementing such a receiver circuit, a signal transferred via the capacitive interface attains a signal level, which is held constant over a long time until the next edge transition of the digital signal occurs.

A test equipment performs a functional test of an integrated circuit chip as well as a method to perform a functional test of that integrated circuit chip, as provided in the claims.

### BRIEF DESCRIPTION OF THE DRAWINGS

The invention will become more clear with reference to specific embodiments when being taken in conjunction with the drawings.

FIG. 1 projected layout of a 60-ball FBGA-package wiring substrate;

FIG. 2 projected layout of a 84-ball FBGA-package as embodied with four electrical pads at the edges of the wiring substrate and two schematically drawn electrodes of a test equipment;

FIG. 3 side view of a FBGA-chip package having electric pads being mounted on a PCB;

FIG. 4 diagram illustrating a JTAG-interface according to an embodiment of the invention;

FIG. 5 a diagram illustrating a JTAG-interface according to an embodiment of the invention for performing a boundary scan test; and

FIG. 6 an embodiment of a driver and a receiver circuit according to an embodiment of the invention.

### DETAILED DESCRIPTION OF ILLUSTRATIVE EMBODIMENTS

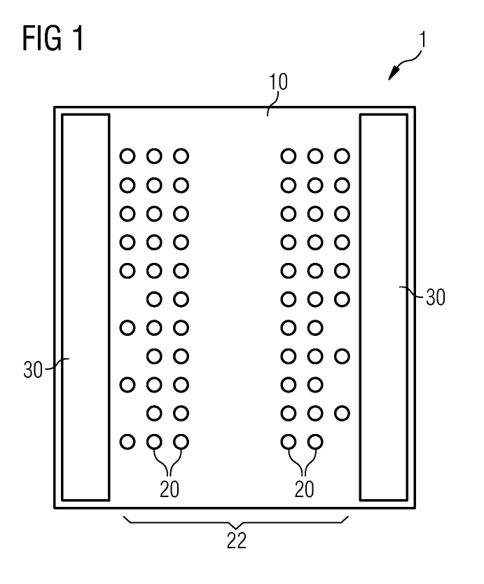

To illustrate the idea of an embodiment of the invention, a schematically drawn projected layout of a 60-ball FBGA-chip package, or more precisely, of the wiring substrate surface, is shown in FIG. 1. The view may also be considered as a bottom perspective of the chip package. Ball-like electrical contacts 20 form a fine-pitch ball-grid array 22 (FBGA) attached on the surface of the wiring substrate 10. The chip package has the size 10.5 mm×10.0 mm. Each ball-like contact has a diameter of roughly 0.4-0.5 mm. The FBGA 22 demonstrated here corresponds to that of a chip package of a memory chip, particularly a chip corresponding to a dynamic random access memory (DRAM).

There are several, e.g., sixty, ball-like electrical contacts distributed over the surface, wherein each contact serves to provide electrical access to a specific data line running through a distribution layer of the wiring substrate 10 over bonding wires to the pins of a chip. In this case, a memory controller communicates via the ball-like contacts 20 with a core logic of the memory chip. The core logic in this case represents the memory cell field and its periphery.

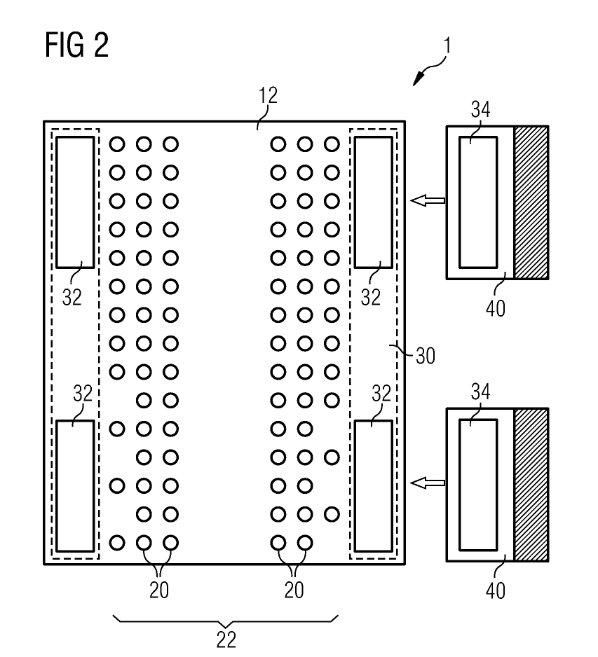

As there are many data lines connecting the memory chip with the memory controller, a large area is consumed by the ball-grid array 22. Nevertheless, the regular array structure leaves areas 30 at the edges of the wiring substrate surface 10 free and unused. According to an embodiment of the invention, this area 30 on the wiring substrate 10 is dedicated to receive electrical pads 32, four of which are shown in FIG. 2.

FIG. 2 shows, for demonstration purposes, a FBGA-chip package 1 having 84 ball-like contacts 20. Similar to the data wirings connecting ball-like contacts 20 with the memory chip, electrical pads 32 are also electrically connected, or at least connectable depending on the circuitry, by wirings of the redistribution layer with the memory chip. As the 84 ball-like contacts 20 provide 84 data lines to the core logic of the memory chip, the four electrical pads 32 provide four data lines to a test circuitry, or a test access port of the memory chip.

The electrical pads 32 each form one electrode of a capacitor. The mutually other capacitor electrode is provided by electrical pad 34, e.g., formed on arm 40 of an automated test equipment (ATE). In order to provide a test interface, a moveable arm 40 shifts the electrical pad 34 into close proximity over electrical pad 32 such that both electrical pads 32, 34 in each of the four cases shown in FIG. 2 form a capacitor. A signal may be transmitted to and from the ATE by means of capacitive coupling between both electrical pads.

It becomes clear from FIG. 2, that using four (or five) electrical pads only, the horizontal alignment of electrical pads 34 provided by a test equipment with electrical pads 32 provided by the chip package 1 is not critical, since their sizes are relatively large as compared with the sizes of the pins of the ball-grid array.

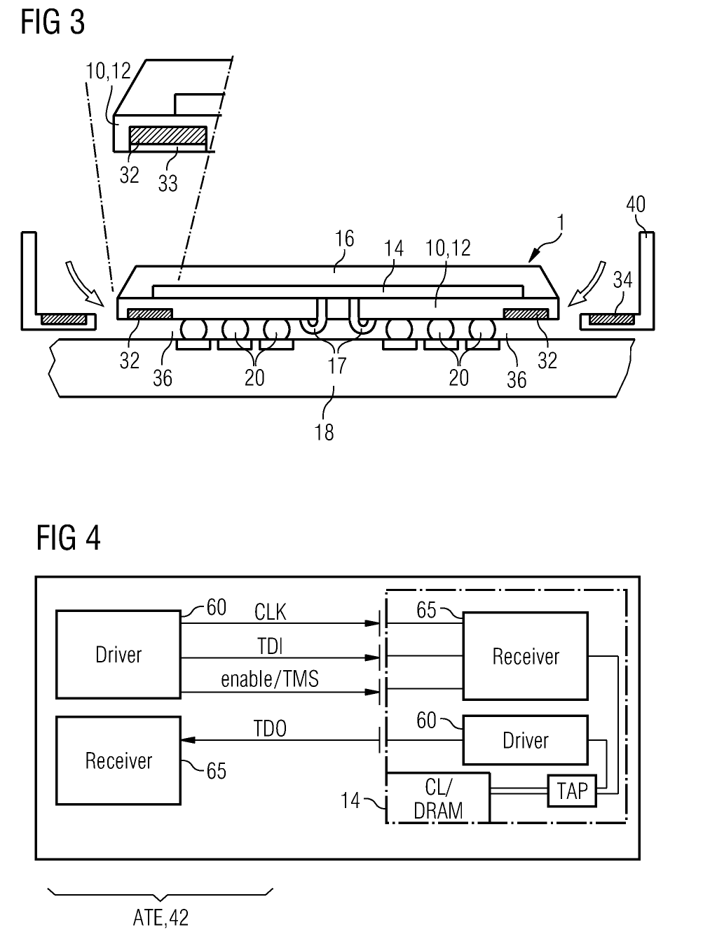

FIG. 3 shows a side view of the chip package shown in FIG. 2. The chip package 1 comprising the IC-chip 14 is mounted to a PCB 18 by means of the ball-like electrical contacts 20. The IC-chip 14 is enclosed in plastic housing 16 and is glued to the wiring substrate 10, 12 by means of an adhesive layer, not shown in FIG. 3. Bonding wires 17 connect metal lines and pads formed on IC-chip 14 with data wires formed within the redistribution layer (not shown) of wiring substrate 10, 12. Those data wirings, which connect the test circuitry and the test access port of IC-chip 14 with the electrical pads 32 analogously run through the redistribution layer of wiring substrate 10, 12.

When a functional test of the chip 14 is to be performed, arms 40 of the ATE enter the small volume space 36 between the chip package 1 and the PCB 18 such as to achieve close proximity between electrical pads 32 and 34. As an adjacent chip package 1 will be very closely located to the chip package 1 shown in FIG. 3, arms 40 will enter the small volume space 36 not necessarily from the longitudinal edge as shown in FIG. 3. Entering this space volume 36 from a transversal side may be performed as well. As the space volume corresponds to the diameter of the ball-like contacts, which thus amounts to roughly 0.5 mm, precise vertical alignment of arms 40 with the complete module may be essential.

The desired capacitor characteristics can be achieved by providing a dielectric material 33 as a thin layer upon the electrical pad 32 as shown in FIG. 3. The thickness of this layer dielectric material 33 as well as its dielectric constant may be appropriately chosen according to the needs or requirements of the capacitive test interface.

FIG. 4 sketches the capacitive test interface for providing the communication between the ATE 42 and the IC-chip 14. The capacitive test interface implemented here corresponds to the JTAG boundary scan architecture, a standard which was written by the Joint Test Action Group (JTAG) having IEEE number 1149. This standard defines a 4 or 5-pin serial protocol for accessing and retrieving test functions performed on printed circuit boards and/or chip packages.

According to this standard a driver 60 on the side of the ATE 42 transmits a clock signal CLK, an input data signal TDI, and an enable/test mode select signal TMS. Each signal has its own data wiring, and accordingly its own capacitor electrode, i.e., electric pad. When this pad 34 is brought into close proximity with electrical pad 32 formed in wiring substrate 10, 12 of chip package 1, the corresponding signals are transferred via capacitive coupling to a receiver 65 each being arranged on the side of the chip package 1. The receiver 65 may be formed within wiring substrate 10, 12 or within chip 14.

Depending on whether the enable/TMS signal incorporates a further test reset signal (TRST) or whether this signal has its own data line, a fourth or fifth data line performs the data retrieval of output test data. This data line is driven by a driver on the side of chip 14. The signal is transmitted via electrical pads 32, 34 to a receiver on the side of the ATE 42. The receiver and the driver of the IC-chip 14 are controlled by a test access port TAP. The TAP controls the test performed on the DRAM-chip 14.

FIG. 5 shows the working principle of the boundary scan test operating to perform a functional test of a core logic CL or the DRAM-chip array 14, respectively. With initialization of a test sequence by means of the enable and clock signals TMS, CLK (or TRST for test reset), instructions laid down in specific instruction registers of the TAP operate to process data serially contained in boundary cells 50. Therein, processing of these data is either effected by access through pins 52 or through the core logic CL.

The finally processed data is then transferred back to the ATE 42 over the data line TDO by means of capacitive coupling over the interface formed by electrical pads 32, 34. In order to demonstrate the different mode of access, FIG. 5 also shows, on the right-hand side, the connection of pin 52 with ball-like contacts 20 providing connection to the PCB 18, wherein wiring pads 19 are formed.

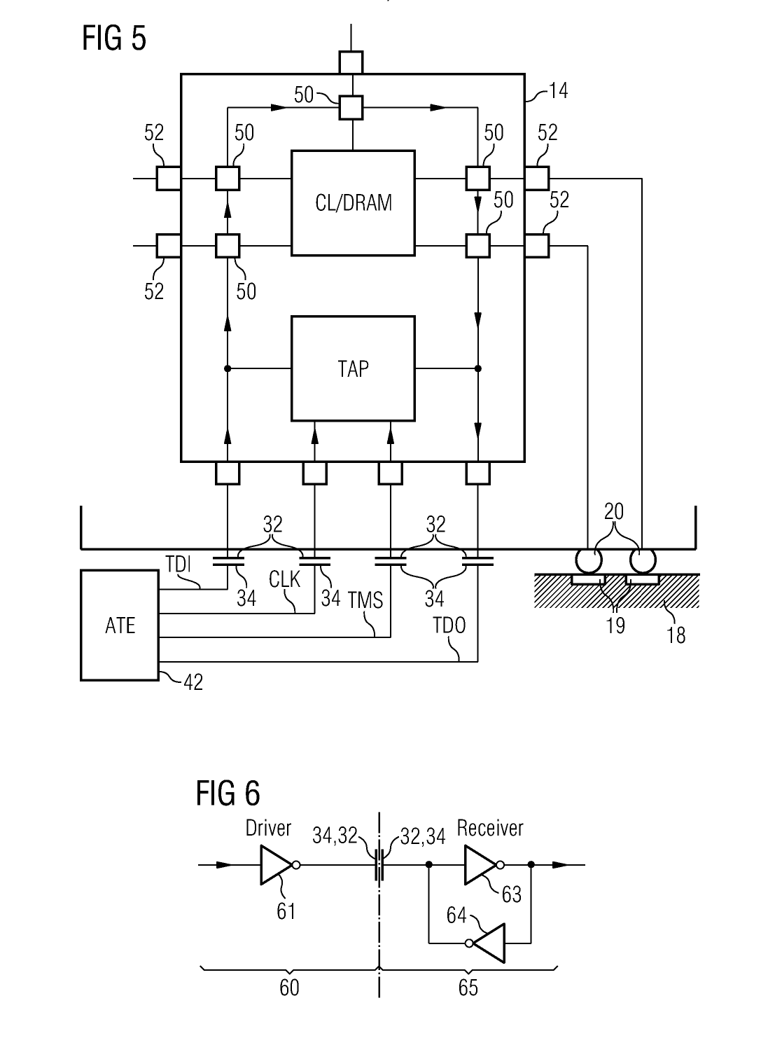

FIG. 6 shows an example of a capacitive test interface. A driver 60 is formed by an inverter 61. The receiver 65 comprises an inverter 63 and a further inverter 64 arranged in a feedback loop in order to prolong the decay of the signal level on the receiver's side. As a result, the signal level is held until the next edge transition of the digital signal, which is transferred for test purposes, arrives on the receiver's side.

The interface as shown in FIG. 6 may be implemented both with the receiver on the chip package's side and the driver on the ATE's side as well as the complementary configuration. With respect to the chip package, it is also possible to have the receiver, or driver respectively, arranged on the chip while the electric pad is formed on the wiring substrate. Therein, both the pad and the receiver, or driver are electrically connected with each other via conductive traces running through the redistribution layer of the wiring substrate.

Although embodiments of the invention have been elucidated on the basis of the accompanying drawings in the description, it is emphasized that the invention is not restricted to the embodiments as depicted in the drawings. This invention equally encompasses derivative embodiments differing from the embodiments as presented herein, but which are within the scope of the present claims.

What is claimed is:

1. An integrated circuit chip package, comprising:
an integrated circuit chip having a core logic and a test access port for performing a functional test of a chip circuitry and/or the core logic;
a housing for protecting the chip;
a wiring substrate for providing an electrical access to the core logic and the test access port; and
at least one electric pad provided as a capacitor electrode on a surface of the wiring substrate, the at least one electric pad being electrically connected with the test access port and being arranged to form a capacitor in combination with an external electric pad of an external test equipment, for transferring a signal between the test equipment and the test access port of the chip by means of capacitive coupling.

2. The chip package according to claim 1, further comprising a set of ball-like electrical contacts for electrically connecting the chip circuitry and the core logic with a printed circuit board, wherein the set of electrical contacts forms a ball grid array, which is provided on the surface of the wiring substrate along with the at least one electric pad.

3. The chip package according to claim 2, wherein
the set of ball-like electrical contacts is arranged to cover an inner portion of the wiring substrate surface, and the at least one electric pad is arranged to cover an outer portion of the surface along an edge of the wiring substrate such as to provide access for an external electric pad of a test equipment to the electric pad of the chip package, wherein the chip package is designed to be mounted to a printed circuit board.

4. The chip package according to claim 1, further comprising:
a receiver circuit, coupled to the at least one electric pad formed on the wiring substrate for receiving and converting a signal that is transferred from an external electric pad to the electric pad by means of capacitive coupling, into a signal that can be detected and processed by the test access port.

5. The chip package according to claim 4, wherein:
the receiver circuit comprises a first inverter and a second inverter, the second inverter being arranged in a feedback loop, such that a signal output from the first inverter is inverted by the second inverter and is fed back to the input of the first inverter, the input of the first inverter further being electrically connected with the electric pad.

6. The chip package according to claim 1, further comprising:
a driver circuit, coupled to the at least one electric pad formed on the wiring substrate for driving the electric pad formed on the surface of the wiring substrate with a signal that is transferred from the test access port to the electric pad, in order to transmit the signal by means of capacitive coupling towards the external electric pad.

7. The chip package according to claim 6, wherein the driver circuit comprises an inverter.

8. The chip package according to claim 1, wherein the at least one electric pad comprises:
one electric pad that is provided on the surface of the wiring substrate, the one electric pad being electrically connected to both a driver circuit and a receiver circuit, and being arranged to serially receive a clock signal, a test data input signal and a test mode select signal and to transmit a test data output signal by means of capacitive coupling.

9. The chip package according to claim 1, wherein the at least one electric pad comprises four electric pads, of which three electric pads are arranged to receive each one of a clock signal, a test data input signal and a test mode select signal by means of capacitive coupling, and of which one electric pad is arranged to transmit a test data output signal.

10. The chip package according to claim 1, wherein the test access port, which is arranged to be electrically connected with the at least one electric pad, is further arranged to control a boundary scan test of a circuitry of the chip and/or the core logic.

11. The chip package according to claim 1, wherein the at least one electric pad is covered with a layer of dielectric material to provide a capacitor dielectric.

12. An interface for performing a functional test of an integrated circuit chip, the interface comprising:
a first electric pad;
a driver circuit associated with the first electric pad;
a second electric pad; and
a receiver circuit associated with the second electric pad,
wherein both the first and second electric pads are arranged to form a capacitor when brought into proximity with respect to each other, one of the first or second electric pads being arranged on a wiring substrate surface of an integrated circuit chip package, the other of the first or second electric pads being arranged on a test equipment, which is designed to perform the functional test of an integrated circuit chip.

13. A test apparatus for performing a functional test of an integrated circuit chip, which forms a constituent part of the chip package, the test apparatus comprising at least one electrode having an electric pad, wherein the electric pad is associated with a driver circuit for transmitting a test data signal to the chip and/or with a receiver circuit for receiving a test data signal from the chip by means of capacitive coupling of the electric pad with another electric pad formed on a wiring substrate surface of the chip package and being electrically connected with a test access port on the chip.

14. The test apparatus according to claim 13, further comprising a set of four or five electric pads in order to perform a boundary scan test of the integrated circuit chip.

15. A method of performing a functional test of an integrated circuit chip, that is packaged in an integrated circuit chip package and which is mounted on a printed circuit board using a test equipment, the method comprising:
providing the printed circuit board with the chip package to the test equipment;
bringing at least one electric pad of the test equipment in close proximity to a respective electric pad of the chip package;
inputting an input test data signal into the chip package by means of capacitive coupling between the electric pads of the test equipment and the chip package;
performing a functional test of the integrated circuit chip contained within the chip package and obtaining output test data in response to input test data;
outputting the obtained output test data from the integrated circuit chip to the test equipment by means of capacitive coupling between the electric pads of the chip package and the test equipment; and
removing the electric pads of the test equipment from the electric pads of the chip package.

16. The method according to claim 15, further comprising rejecting or accepting the integrated circuit chip based on the output test data.
